(19) United States
(12) Patent Application Publication
(10) Pub. No.: US 2017/0002463 A1
(43) Pub. Date: Jan. 5, 2017

(54) SHOWERHEAD AND A THIN-FILM DEPOSITION APPARATUS CONTAINING THE SAME

(71) Applicant: EPISTAR CORPORATION, Hsinchu (TW)

(72) Inventors: Nai-Wen Fan, Hsinchu (TW); Shau-Yi Chen, Hsinchu (TW); Ai-Sen Liu, Hsinchu (TW); Zhi Zhong Ke, Hsinchu (TW); Chien-Bao Lin, Hsinchu (TW); Wen-Hao Zhuo, Hsinchu (TW); Feng-Zhi Chen, Hsinchu (TW); Chien-Cheng Kuo, Hsinchu (TW); Shih-Hao Chan, Hsinchu (TW); Chih-Hao Chen, Hsinchu (TW); Wei-Chih Peng, Hsinchu (TW); Chia-Liang Hsu, Hsinchu (TW)

(21) Appl. No.: 15/198,649

(22) Filed: Jun. 30, 2016

(30) Foreign Application Priority Data
Jun. 30, 2015 (TW) 104121229
Jun. 30, 2015 (TW) 104121230
Jun. 30, 2015 (TW) 104121234

(51) Int. Cl. C23C 16/455

(52) U.S. Cl. CPC C23C 16/45525; C23C 16/45565

(57) ABSTRACT

A thin-film deposition apparatus comprises a chamber; a carrier in the chamber; a showerhead on the carrier, wherein the showerhead comprises multiple first gas-dispensing holes, multiple second gas-dispensing holes and multiple plasma-generating portions; and a first gas inlet system for providing a first process gas, wherein the first process gas outputted from the multiple first gas-dispensing holes.

### TECHNICAL FIELD

This present application is related to a showerhead and a thin-film deposition apparatus containing the same, and especially related to a multi-mode showerhead and a multi-mode thin-film deposition apparatus.

### RELATED APPLICATION DATA

This application claims the right of priority of TW Application No. 104121230, which is filed on Jun. 30, 2015, TW Application No.104121229, which is filed on Jun. 30, 2015, TW Application No. 104121234, which is filed on Jun. 30, 2015, and the content of which are hereby incorporated by reference in their entireties.

### DESCRIPTION OF BACKGROUND ART

The traditional methods for forming thin films of a light-emitting diode comprise Molecular Beam Epitaxy (MBE), Chemical Vapor Deposition (CVD), Plasma Enhanced Chemical Vapor Deposition (PECVD), Atomic Layer Epitaxy (ALE) or Atomic Layer Deposition (ALD), wherein PECVD and ALD being applied for forming thin films of a light-emitting diode become more popular.

For technology nowadays, PECVD and ALD should be performed in different processing chambers so the thin film of the light-emitting diode should be transferred between different processing chambers. In that case, the cost of equipment which is able to perform PECVD and ALD is high, and the quality of the thin films is low because the thin films are exposed in air during transferring process.

### SUMMARY OF THE DISCLOSURE

A thin-film deposition apparatus comprises a chamber; a carrier in the chamber; a showerhead on the carrier, wherein the showerhead comprises multiple first gas-dispensing holes, multiple second gas-dispensing holes and multiple plasma-generating portions; and a first gas inlet system for providing a first process gas, wherein the first process gas outputted from the multiple first gas-dispensing holes.

A method of thin-film deposition, comprising steps of providing a chamber; proving a substrate in the chamber; forming a first thin film on the substrate in a first thin-film deposition mode; and forming a second thin film on the first thin film in a second thin-film deposition mode; wherein the first thin-film deposition mode comprises Atomic Layer Deposition, the second thin-film deposition mode comprises Plasma Enhanced Chemical Vapor Deposition, and the first thin-film deposition mode and the second thin-film deposition mode are performed in the chamber.

A thin-film deposition apparatus comprises a chamber; a carrier in the chamber; and a showerhead on the carrier, wherein the shower comprises an upper surface; a lower surface opposite to the upper surface, wherein the lower surface comprises a normal; multiple first gas-dispensing holes on the lower surface; a gas inlet hole, wherein a first process gas is transferred into the multiple first gas-dispensing holes through the gas inlet hole; and a gas supply pipeline connecting between the gas inlet hole and the multiple first gas-dispensing holes, wherein the first process gas enters the multiple first gas-dispensing holes through the gas supply pipeline; wherein the first process gas can be dispensed from the first gas-dispensing hole in a gas dispensing direction, and the gas dispensing direction and the normal have an acute angle β between thereof.

### BRIEF DESCRIPTION OF THE DRAWINGS

FIG. 1 shows a cross-sectional view of a thin-film deposition apparatus in accordance with one embodiment disclosed in present application;

FIG. 2A shows top-views of the first gas plate 150A and the second gas plate 150B of the showerhead 150 of the thin-film deposition apparatus shown in FIG. 1;

FIG. 2B shows a schematic diagram of gas dispensing directions of the first gas-dispensing holes 153 and the second gas-dispensing holes 154 of the first gas plate 150A on the cross-sectional line B-B′ in FIG. 2A;

FIG. 2C shows a cross-sectional view of the showerhead 150 along cross-sectional line B-B′ shown in FIG. 2A;

FIG. 2D shows an enlarged cross-sectional view of the gas distributing plate 170 shown in FIG. 1

FIGS. 2E and 2E′ show the detailed cross-sectional view of the electrode 177 and the plasma-generating portion between the first opening 166 and the second recess 152;

FIG. 2F shows the cross-sectional view of the main gas supply pipeline 160 and the branch pipelines 164 of the second gas plate 150B along the cross-sectional line A-A′ in FIG. 2A;

FIG. 3 shows the top view of the carrier 140 disclosed in the FIG. 1;

FIG. 4 shows the schematic diagram of the process gas flowing in the thin-film deposition apparatus during the first thin-film deposition mode;

FIG. 5 shows the schematic diagram of the process gas flowing in the thin-film deposition apparatus during the second thin-film deposition mode;

FIGS. 6A and 6B show a process flow of forming a composite layer on a semiconductor layer by using the thin-film deposition apparatus in accordance with one embodiment in present application, wherein the composite layer comprises graphene layer and metal layer;

FIGS. 7A-7C show a process flow of forming a semiconductor device by using the thin-film deposition apparatus in accordance with one embodiment in present application.

### DETAILED DESCRIPTION OF PREFERRED EMBODIMENTS

The embodiments of the application are illustrated in details, and are plotted in the drawings. The same or the similar parts in the drawings and the specification have the same reference numeral. In the drawings, the shape and thickness of a specific element could be shrunk or enlarged. It should be noted that the element which is not shown in the drawings or described in the following description could be the structure well-known by the person having ordinary skill in the art.

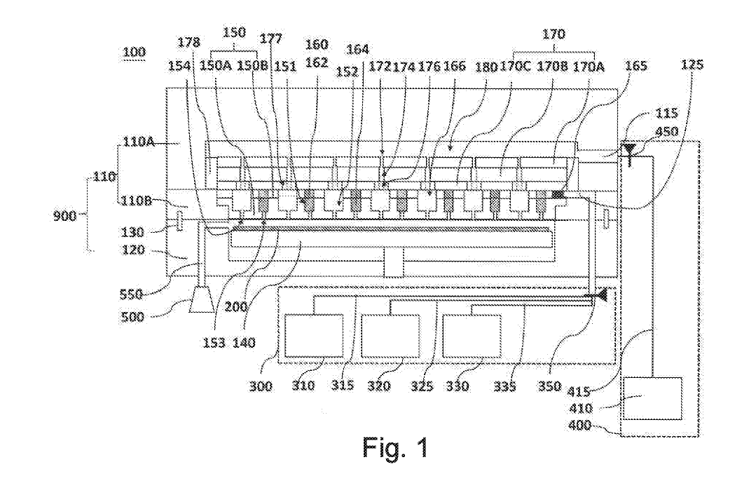

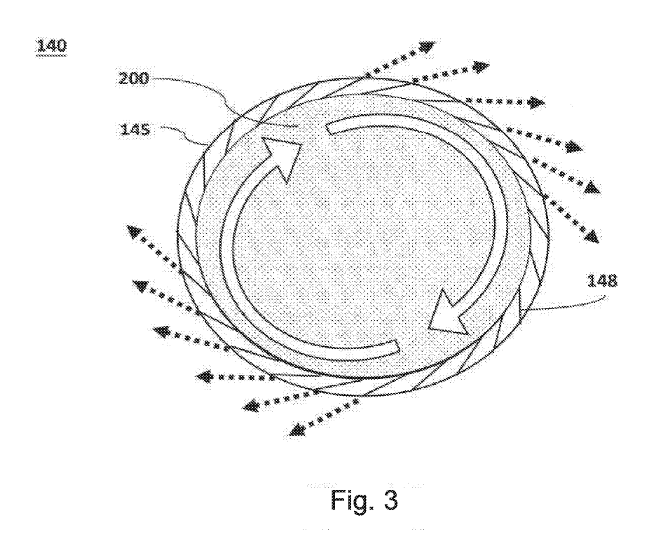

Firstly, FIG. 1 shows a cross-sectional view of a thin-film deposition apparatus 100 in accordance with an embodiment in present application. The thin-film deposition apparatus 100 comprises a chamber 900 which comprises a lower chamber 120, an upper chamber 110 on the lower chamber 120, and a fixing part 130 between the lower chamber 120 and the upper chamber 110 for connecting thereof, wherein the upper chamber 110 comprises an upper part 110A and a lower part 110B. In the chamber 900, there are a carrier 140 surrounded by a gas barrier ring 145 (shown in FIG. 3) disposed in the lower chamber 120 for carrying a substrate 200 and a plasma generating system located on the upper part 110A and the carrier 140, which comprises a gas inlet room 180 and a gas distributing plate 170. Besides, the thin-film deposition apparatus in an embodiment further comprises a first gas inlet system 300 for providing a first process gas during the first thin-film deposition mode; and a second gas inlet system 400 connecting to the plasma generating system for providing a second process gas during the second thin-film deposition mode. In the chamber 900, there is a showerhead 150 for vapor deposition disposed on the carrier 140 and in the lower part 110B, wherein the showerhead 150 comprises a first gas plate 150A and a second gas plate 150B.

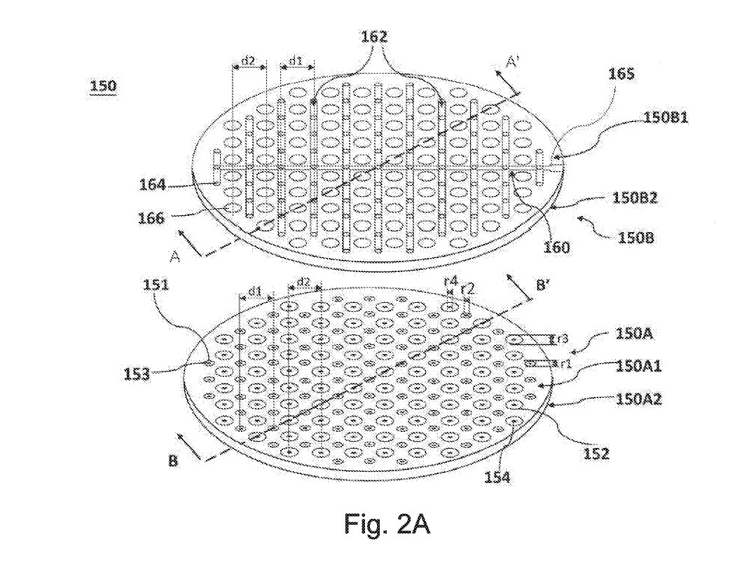

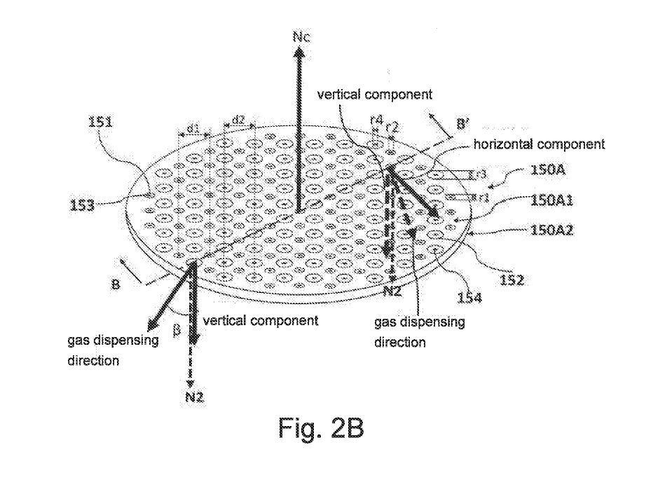

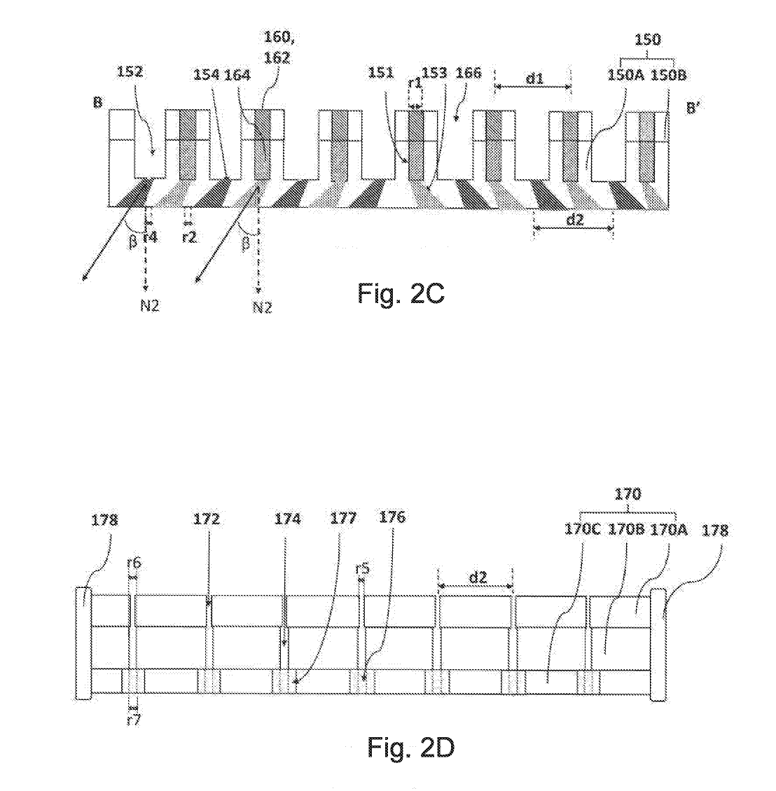

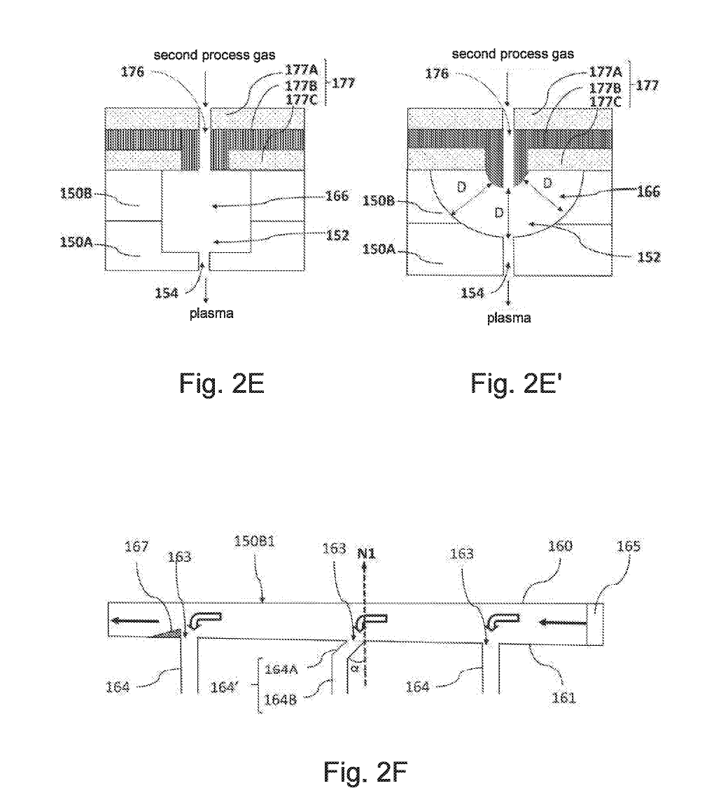

Then, FIG. 2A shows a top view of the first gas plate 150A and the second gas plate 150B of the showerhead 150 used for vapor deposition. As FIG. 2A shows, the first gas plate 150A has a first upper surface 150A1 and a first lower surface 150A2 opposite to the first upper surface 150A1. The first gas plate 150A comprises multiple first recesses 151, wherein each of the first recesses 151 has a first diameter r1 between 3 mm and 9 mm, and multiple second recesses 152, wherein each of the second recesses 152 has a third diameter r3 between 5 mm and 15 mm. The multiple first recesses 151 are aligned with an interval of a first distance d1 between any two neighboring first recesses 151 on the first upper surface 150A1, wherein each of the multiple first recesses 151 comprises a first gas-dispensing hole 153 having a second diameter r2 between 0.5 mm and 2.5 mm and penetrating the first gas plate 150A to the first lower surface 150A2. The multiple second recesses 152 are aligned with an interval of a second distance d2 on the first upper surface 150A1, wherein each of the multiple second recesses 152 comprises a second gas-dispensing hole 154 having a fourth diameter r4 between 0.5 mm and 2.5 mm and penetrating the first gas plate 150A to the first lower surface 150A2. The multiple first recesses 151 and the multiple second recesses 152 are arranged alternately.

As FIG. 2A shows, the second gas plate 150B has a second upper surface 150B1 and a second lower surface 150B2 opposite to the second upper surface 150B1. The second gas plate 150B comprises a first gas inlet hole 165 connecting to the first gas inlet system 300 (shown in FIG. 1) for importing the first process gas during the first thin-film deposition mode. The second gas plate 150B further comprises a main gas supply pipeline 160, which connects the first gas inlet hole 165 and is disposed on the second gas plate 150B; multiple auxiliary gas supply pipelines 162, which are spaced apart from each other, connect to the main gas supply pipeline 160 separately, and are disposed on the second gas plate 150B; and multiple branches 164 formed on the main gas supply pipeline 160 and multiple auxiliary gas supply pipelines 162. The multiple branches 164 are aligned with an interval of a first distance d1t and penetrate the second gas plate 150B from the second upper surface 150B1 to the second lower surface 150B2. Each of the multiple branches 164 is corresponding to each of the multiple first recesses 151 on the first gas plate 150A. In the embodiment, the first thin-film deposition mode is ALD. During the first thin-film deposition mode, the first process gas enters the main gas supply pipeline 160 and the multiple auxiliary gas supply pipelines 162 via the first gas inlet hole 165. The first process gas is then guided into the multiple first recesses 151 via the main gas supply pipeline 160 and the multiple auxiliary gas supply pipelines 162. Next, the first process gas is sprayed uniformly on a surface of the substrate 200 via the first gas-dispensing hole 153 of each of the multiple first recesses 151.

Besides, the second gas plate 150B further comprises multiple first openings 166 formed in the region beyond the main gas supply pipeline 160 and the multiple auxiliary gas supply pipelines 162. The multiple first openings 166 are aligned with an interval of a second distance d2 between any two neighboring first openings 166 and penetrate the second gas plate 150B from the second upper surface 150B1 to the second lower surface 150B2. Each of the multiple first openings 166 is corresponding to each of the multiple second recesses 152 on the first gas plate 150A. The multiple first openings 166 and the multiple second recesses 152 corresponding to thereof form multiple plasma-generating portions arranged in a matrix. During the second thin-film deposition mode, plasma is able to be formed in the multiple plasma-generating portions and sprayed on the surface of the substrate 200 via the second gas-dispensing hole 154 in each of the multiple second recesses 152.

Next, FIG. 2B shows a schematic diagram of gas dispensing directions of the first gas-dispensing holes 153 and the second gas-dispensing holes 154 of the first gas plate 150A on the cross-sectional line B-B′ in FIG. 2A. The gas dispensing directions of the first gas-dispensing holes 153 and the second gas-dispensing holes 154 on the cross-sectional line B-B′ have acute angles β corresponding to the second normal direction N2. The horizontal components of the gas dispensing directions of the first gas-dispensing holes 153 and the second gas-dispensing holes 154 are perpendicular to the straight line which passes through the first gas-dispensing holes 153, the second gas-dispensing holes 154, and a normal Nc passing through the central axis of the first gas plate 150A. All of the first gas-dispensing holes 153 and the second gas-dispensing holes 154 are disposed in the first gas plate 150A according to the same rule. In one embodiment, the range of the acute angle β is 30°≦β≦60°. In the embodiment, the gas dispensing directions of the each first gas-dispensing hole 153 and the each second gas-dispensing hole 154 have acute angles β corresponding to the second normal direction N2, so, besides of a vertical component of the gas dispensing on the surface of the substrate 200, the horizontal components of the gas dispensing form a clockwise vortex. Although the vortex is clockwise in the embodiment, the gas dispensing directions of the first gas-dispensing holes 153 and the second gas-dispensing holes 154 can be adjusted to make the horizontal components of the gas dispensing form a counterclockwise vortex.

FIG. 2C shows a cross-sectional view of the showerhead 150 along cross-sectional line B-B′ shown in FIG. 2A, wherein the showerhead 150 is formed of the first gas plate 150A and the second gas plate 150B. As shown in FIG. 2B, each of the multiple branches 164 on the main gas supply pipeline 160 or the multiple auxiliary gas supply pipelines 162 of the second gas plate 150B is aligned with and extends into each of the multiple first recesses 151 on the first gas plate 150A. During the first thin-film deposition mode, the first process gas is sprayed on the surface of the substrate 200 (shown in FIG. 1) via the first gas-dispensing hole 153. Each of the multiple first openings 166 on the second gas plate 150B is corresponding to each of the multiple second recesses 152 on the first gas plate 150A. During the second thin-film deposition mode, the second process gas in the gas inlet room 180 (shown in FIG. 1) passes through the gas distributing plate 170 (shown in FIG. 1) to form the plasma, which is necessary during the second thin-film deposition mode. The plasma passes through the first openings 166 and enters the second recesses 152, which are arranged as a matrix, to form plasma sources. The plasma is then sprayed uniformly on the surface of the substrate 200 (shown in FIG. 1) via the second gas-dispensing hole 154 in each of the multiple second recesses 152.

As mentioned above, the gas dispensing directions of the first gas-dispensing holes 153 and the second gas-dispensing holes 154 have acute angles β corresponding to the normal N2 perpendicular to the first gas plate 150A. Besides, in order to improve the efficiency of the first gas-dispensing holes 153 dispensing the first process gas, the cross-sectional area of each of the first gas-dispensing holes 153 is larger as each of the first gas-dispensing holes 153 is near the first lower surface 150A2, which makes the dispensing covering region of each of the first gas-dispensing holes 153 larger and the dispensing covering regions of the adjacent first gas-dispensing holes 153 overlaps. Similarly, the second gas-dispensing holes 154 can be designed by the same rule.

FIG. 2D shows an enlarged cross-sectional view of the gas distributing plate 170 shown in FIG. 1. The gas distributing plate 170 comprises a first gas distributing plate 170A, a second gas distributing plate 170B, and a third gas distributing plate 170C fixed by a quartz ring 178, wherein the first gas distributing plate 170A and the third gas distributing plate 170C are made of electrically insulated material, such as quartz. The first gas distributing plate 170A comprises multiple third gas-dispensing holes 172, wherein each of the third gas-dispensing holes 172 having a fifth diameter r5 between 0.5 mm and 2.5 mm. The third gas-dispensing holes 172 are aligned with an interval of a second distance d2 between any two neighboring third gas-dispensing holes 172 and penetrate the first gas distributing plate 170A. The second gas distributing plate 170B is disposed under the first gas distributing plate 170A. The second gas distributing plate 170B comprises multiple fourth gas-dispensing holes 174, wherein each of the fourth gas-dispensing holes 174 has a sixth diameter r5 of between 0.5 mm and 5 mm. The fourth gas-dispensing holes 174 are aligned with an interval of a second distance d2 between any two neighboring fourth gas-dispensing holes 174 and penetrate the second gas distributing plate 170B, wherein each of the multiple fourth gas-dispensing holes 174 is corresponding to each of the multiple third gas-dispensing holes 172. The third gas distributing plate 170C is disposed between the second gas distributing plate 170B and the second gas plate 150B of the showerhead 150. The third gas distributing plate 170C comprises multiple electrodes 177 which are aligned with an interval of a second distance d2 between any two neighboring electrodes 177 and penetrate the third gas distributing plate 170C, wherein a fifth gas-dispensing hole 176 with a seventh diameter r7 is disposed in each of the multiple electrodes 177. Besides, the diameter of the third gas-dispensing hole 172 is smaller than the diameter of the fourth gas-dispensing holes 174.

FIG. 2E shows the detailed cross-sectional view of the electrode 177 and the plasma-generating portion, wherein the electrode 177 comprises a metallic electrode 177B and electrically insulative dielectric layers 177A, 177C which sandwich the metallic electrode 177B. As shown in FIG. 2E, the metallic electrode 177B connects with a voltage source (not show), and the first gas plate 150A and the second gas plate 150B are made of metallic material, grounded and electrically insulated from the metallic electrode 177B. When the second process gas enters plasma-generating portion, which is between the first opening 166 and the second recess 152 corresponding to thereof, via the fifth gas-dispensing hole 176, a bias voltage makes the second process gas to form plasma, while the bias voltage is provided by the metallic electrode 177B connecting with a voltage source and the grounded first gas plate 150A and the second gas plate 150B. Then, the plasma is sprayed uniformly via the second gas-dispensing hole 154 in the second recess 152. FIG. 2E shows a cylinder plasma-generating portion, wherein the metallic electrode 177B is a flat electrode. In another embodiment, the plasma-generating portion can be modified as concentric spherical upper and lower electrodes as shown in FIG. 2E′. For the plasma-generating portion having a bowl shape, there is a fixed distance D between the surface of the second gas plate 150B revealing from the first opening 166 and the metallic electrode 177B, and also between the surface of the first gas plate 150A revealing from the second recess 152 and the metallic electrode 177B. Therefore, comparing with the cylinder plasma-generating portion, the plasma-generating portion with bowl shape has more uniform electrical potential distribution and the plasma density, and the heat from the plasma formation can be distributed uniformly without concentration. Furthermore, there is no corner in the bottom of the cylinder so the number of the particles produced during the process can be reduced.

Next, FIG. 2F shows the cross-sectional view of the main gas supply pipeline 160 and the branches 164 of the second gas plate 150B along the cross-sectional line A-A′ in FIG. 2A. As shown in FIG. 2F, in order to solve the problem of the uneven distribution of the flow velocity of the first process gas in the main gas supply pipeline 160, the main gas supply pipeline 160 comprises a first inclined wall 161 near the second lower surface 150B2 of the second gas plate 150B, which makes the cross-sectional area of the main gas supply pipeline 160 smaller as the cross-sectional area of the main gas supply pipeline 160 is more distant from the first gas inlet hole 165. The first incline wall 161 comprises multiple gas holes 163 arranged at an interval of a first distance d1 between any two neighboring gas holes 163 on thereof. The branch 164, which originally is perpendicular to the second upper surface 150B1 and connects the multiple gas holes 163, can be reformed to be a curved branch 164′ comprising a curved portion 164A and a vertical portion 164B, wherein an acute angle α is formed between the curved portion 164A and a first normal N1 passing through the second upper surface 150B1 and the vertical portion 164B is perpendicular to the second upper surface 150B1, which makes the first process gas in the main gas supply pipeline 160 flow into the curved portion 164A more easily. Besides, a baffle block can be disposed on the lee of the edge of the gas hole 163 which connects the branch 164 and/or the curved branch 164′, for increasing the amount of the first process gas flowing into the branch 164 and/or the curved branch 164′. Similarly, the auxiliary gas supply pipelines 162 can be designed by the same rule.

FIG. 3 shows the top view of the carrier 140 disclosed in the FIG. 1. As shown in FIG. 3, a substrate 200, which is used for thin-film deposition, is disposed on the surface of the carrier 140, and a gas barrier 145, which is a ring shape, is on the carrier 140 and surrounds the carrier 140. In another embodiment, the gas barrier 145 and the carrier 140 are separated from a distance. The gas barrier 145 comprises multiple drain channels 148 which are spaced apart to each other. The multiple drain channels 148 are able to be disposed inwardly on the upper surface or the lower surface of the gas barrier 145. Each direction of the drain channels 148 is corresponding to the tangential direction of vortex gas. In other words, there is an angle between the direction of the drain channel 148 and the radial direction from the center to the circumference of the ring shape of the gas barrier 145. As the drain system operates, the plasma formed of the first process gas and the second process gas is able to be drained from the drain channels 148 and away the thin-film deposition apparatus 100 for improving the effect of the clockwise or the counterclockwise vortex which is formed by the gas dispense from the first gas-dispensing holes 153 and/or the second gas-dispensing hole 154. As the two arc arrows inside the ring shape show, the vortex gas approximately flows around the center of the ring shape to make the process gas distribute uniformly in the chamber 100. As shown in FIG. 1, the first gas inlet system 300 disclosed in the embodiment comprises a first precursor gas supply 310, a second precursor gas supply 320, a clean gas supply 330, a first process gas pipe 125, of which one end connects the first gas inlet hole 165 of the second gas plate 150B and the other end connects a high-pressure control valve 350, a first high-pressure pipe 315 connecting the first precursor gas supply 310 and the high-pressure control valve 350, a second high-pressure pipe 325 connecting the second precursor gas supply 320 and the high-pressure control valve 350, and a third high-pressure pipe 335 connecting the clean gas supply 330 and the high-pressure control valve 350. The first gas inlet system 300 chooses one of the first precursor gas, the second precursor gas and the clean gas to enter the first gas inlet hole 165 by controlling the high-pressure control valve 350. The clean gas can be inert gas, such as nitrogen and noble gas, which is not able to react with the first precursor gas and the second precursor gas.

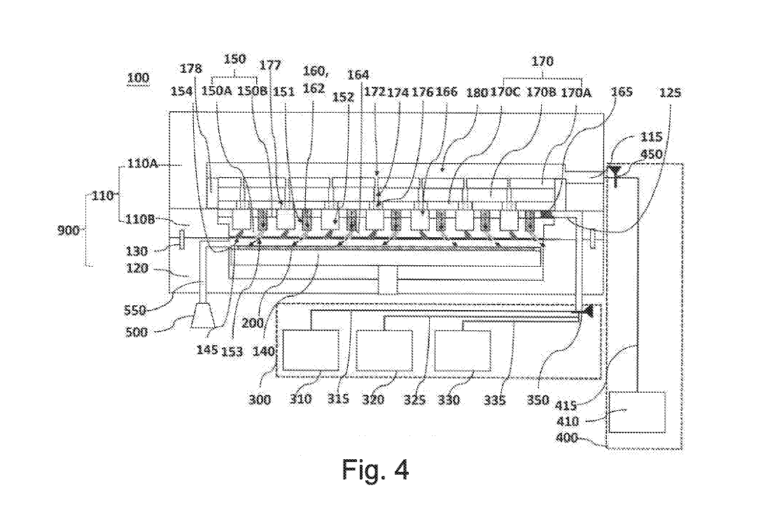

Then, FIG. 4 shows the schematic diagram of the first process gas flowing in the thin-film deposition apparatus during the first thin-film deposition mode. As mentioned above, the first thin-film deposition mode disclosed in the embodiment is ALD. During the first thin-film deposition mode, the first precursor gas supply 310 of the first gas inlet system 300 is turned on to provide the first precursor gas entering into the first gas pipe 125 from the first high-pressure pipe 315 via the high-pressure control valve 350 and then enters the first gas inlet hole 165 of the second gas plate 150B of the showerhead 150. And then, the first precursor gas passes through the main gas supply pipeline 160 and the multiple gas supply branches 162, and enters the multiple first recesses 151 via the multiple branches 164 of the main gas supply pipeline 160 and the multiple gas supply branches 162. Next, the first precursor gas is sprayed on the surface of the substrate 200 via the first gas-dispensing holes 153 of the multiple first recesses 151. In following step, the first precursor gas supply 310 is turned off, and then, the clean gas supply 330 is turned on to conduct the clean gas into the showerhead 150 through the third high-pressure pipe 335 with the abovementioned methods. The first precursor gas remains in the showerhead 150 and the clean gas is exhausted from the chamber 900 through exhaust pipe 550 by using the exhaust pump 500. In the next step, the clean gas supply 330 is turned off, and then, the second precursor gas supply 320 is turned on to conduct the second precursor gas into the showerhead 150 through the second high-pressure pipe 325 with the abovementioned methods and sprayed on the surface of the substrate 200, where a first precursor gas deposits on for making the second precursor gas react with the first precursor gas on the surface of the substrate 200 to form a thin-film. Finally, the second precursor gas supply 320 is turned off, and then, the clean gas supply 330 is turned on to conduct the clean gas into the showerhead 150 through the third high-pressure pipe 335 with the abovementioned methods. And, the first precursor gas remains in the showerhead 150 and the clean gas are exhausted from the chamber 900 through exhaust pipe 550 by using the exhaust pump 500. The above steps form a cycle of ALD, and the demand thickness of the thin-film can be achieved by repeating the cycles of ALD for multiple times.

As shown in FIG. 1, the second gas inlet system 400 disclosed in the embodiment comprises a second gas supply 410, a fourth high-pressure pipe 415 and a high-pressure control valve 450. During the second thin-film deposition mode, the second process gas is provided into a second gas pipe 115 of the gas inlet room 180 through the fourth high-pressure pipe 415 by controlling the high-pressure control valve 450, and then, enters the gas inlet room 180.

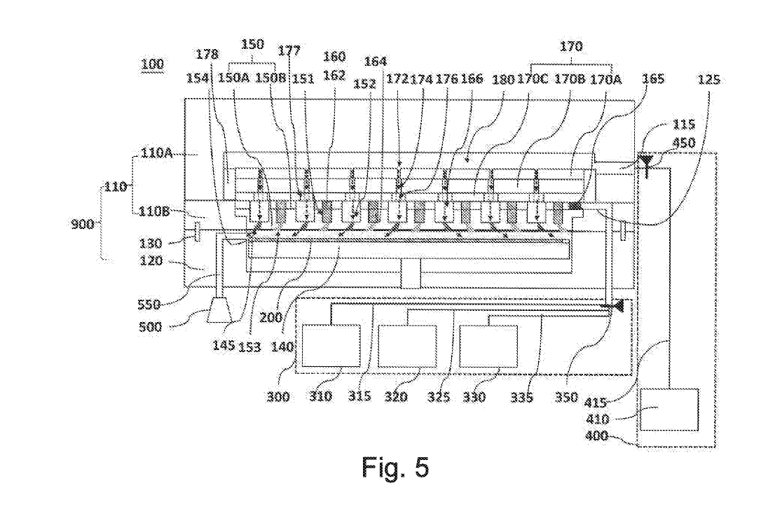

Next, FIG. 5 shows the diagram of the process gas flowing in the thin-film deposition apparatus during the second thin-film deposition mode. As abovementioned, the second thin-film deposition mode disclosed in the embodiment is Plasma Enhanced Chemical Vapor Deposition (PECVD). During the second thin-film deposition mode, the second gas supply 410 of the second gas inlet system 400 is turned on, and the second process gas enters the second gas pipe 115 and the gas inlet room 180 through the fourth high-pressure pipe 415 by controlling the high-pressure control valve 450. The second process gas 190 in the gas inlet room 180 flows through the first gas distributing plate 170A via the multiple third gas-dispensing holes 172; then flows through the second gas distributing plate 170B via the multiple fourth gas-dispensing holes 174; and then enters the multiple plasma-generating portions arranged as a matrix, which are formed of the multiple first openings 166 and the multiple second recesses 152 corresponding to thereof, via the fifth gas-dispensing holes 176 of the third gas distributing plate 170C.

The plasma, which is necessary in the second thin-film deposition mode, is formed in the multiple plasma-generating portions arranged as a matrix, and then the plasma is sprayed uniformly on the surface of the substrate 200 via the second gas-dispensing hole 154 in each of the second recesses 152 to form PECVD thin film. In the embodiment, the second process gas comprises silane, argon, hydrogen, oxygen or the combination thereof.

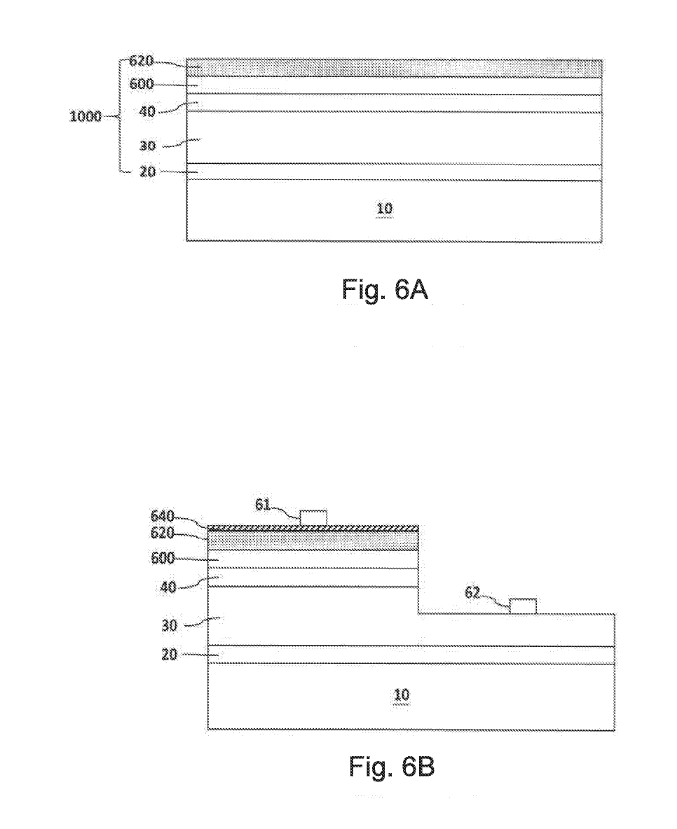

FIGS. 6A and 6B show a processing flow of forming a composite layer on a semiconductor layer by using the thin-film deposition apparatus in accordance with an embodiment disclosed in the application, wherein the composite layer comprises graphene layer and metal layer.

As shown in FIG. 6A, a semiconductor substrate 10 is provided, and an epitaxial stack 1000 is on the semiconductor substrate 10. The epitaxial stack 1000 comprises a buffer layer 20, a first semiconductor layer 30, an active layer 40 and a second semiconductor layer 600, wherein the buffer layer 20, the first semiconductor layer 30, the active layer 4,0 and the second semiconductor layer 600 are sequentially formed on the semiconductor substrate 10. In the embodiment, the first semiconductor layer 30 comprises n-type GaN layer (n-GaN), and the second semiconductor layer 600 comprises p-type GaN layer (p-GaN). And then, by performing the first thin-film deposition mode (ALD) in the thin-film deposition apparatus in accordance with the embodiment, a metal layer 620 with a thickness of smaller than 10 nm is deposited on the surface of the second semiconductor layer 600, wherein the metal layer 620 ohmically contacts with the second semiconductor layer 600. The material of the metal layer 620 comprises Cu, Pt or Ni. By performing the second thin-film deposition mode (PECVD) in the thin-film deposition apparatus, a graphene layer 640 with a thickness of smaller than 5 nm is deposited on the metal layer 620 at temperature lower 350 degree Celsius to form a composite current spreading layer comprising the metal layer 620 and the graphene layer 640, wherein the metal layer 620 ohmically contacts the graphene layer 640 for improving electrical current spreading laterally.

Next, a portion of the metal layer 620, the graphene layer 640, the second semiconductor layer 600 and the active layer 40 are removed to reveal the first semiconductor layer 30 by lithography and etching. Next, a first electrode 61 and a second electrode 62 are respectively formed on the graphene layer 640 and the revealed portion of the first semiconductor layer 30 for conducting the external electrical current.

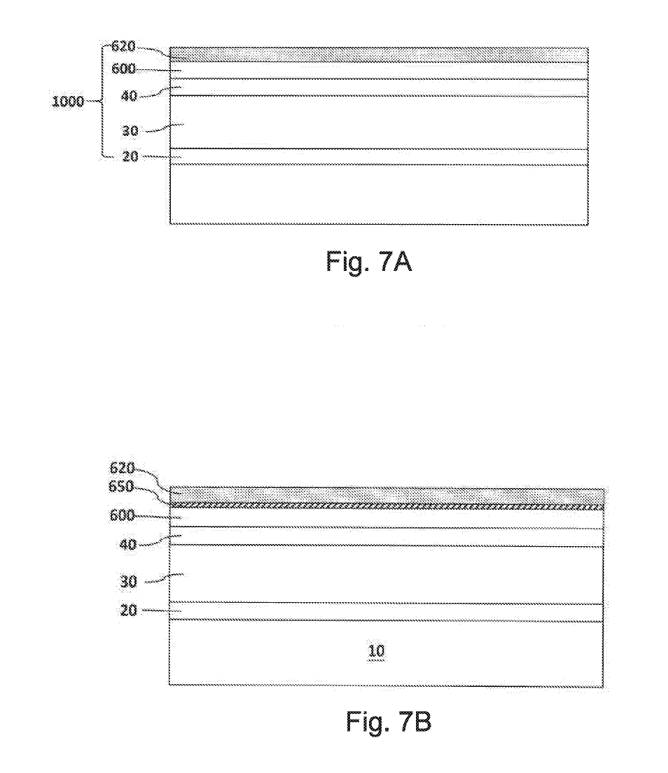

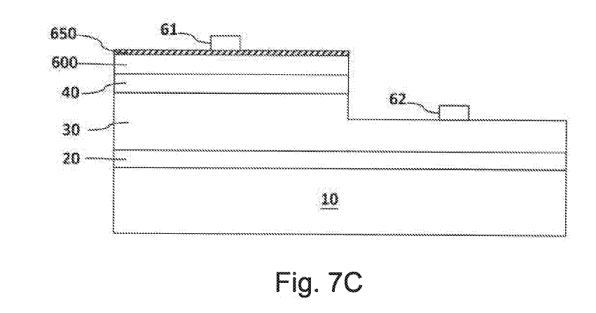

FIGS. 7A-7C show a processing flow of forming a semiconductor device by using the thin-film deposition apparatus in accordance with an embodiment disclosed in the application.

As shown in FIG. 7A, the process of forming the semiconductor device comprises providing a semiconductor substrate 10 and forming an epitaxial stack 1000 on the semiconductor substrate 10. The epitaxial stack 1000 comprises a buffer layer 20, a first semiconductor layer 30, an active layer 40, and a second semiconductor layer 600. In the embodiment, the first semiconductor layer 30 comprises n-type GaN layer (n-GaN), the active layer 40 comprises GaN series material, and the second semiconductor layer 600 comprises p-type GaN layer (p-GaN). By performing the first thin-film deposition mode, such as ALD, a metal layer 620 with a thickness between 1 nm and 10 nm is deposited on the surface of the second semiconductor layer 600 in the thin-film deposition apparatus 100. The material of the metal layer 620 comprises Cu, Pt, or Ni.

Next, as shown in FIG. 7B, by performing the second thin-film deposition mode, such as PECVD, in the thin-film deposition apparatus 100, at a temperature between 700 degree and 1000 degree Celsius, carbon atoms penetrate the metal layer 620 and achieve the surface of the second semiconductor layer 600 to form a graphene layer 650 between the second semiconductor layer 600 and the metal layer 620, wherein the graphene layer 650 has a thickness of between 1 nm and 5 nm and ohmically contacts with the second semiconductor layer 600.

Finally, as shown in FIG. 7C, the metal layer 620 is removed by etching to reveal the graphene layer 650 for forming a transparent electrical current spreading layer. Next, a portion of the graphene layer 650, the second semiconductor layer 600, and the active layer 40 are removed to reveal the first semiconductor layer 30 by lithography and etching. Then, a first electrode 61 and a second electrode 62 are respectively formed on the graphene layer 640 and the revealed portion of the first semiconductor layer 30 for conducting the external electrical current.

Although the present application has been explained above, it is not the limitation of the range, the sequence in practice, the material in practice, or the method in practice. Any modification or decoration for present application is not detached from the spirit and the range of such.

What is claimed is:

1. A thin-film deposition apparatus comprising:
a chamber;
a carrier in the chamber;
a showerhead on the carrier, wherein the showerhead comprises multiple first gas-dispensing holes, multiple second gas-dispensing holes, and multiple plasma-generating portions; and
a first gas inlet system for providing a first process gas, wherein the first process gas outputted from the multiple first gas-dispensing holes.

2. The thin-film deposition apparatus according to claim 1, further comprising a second gas inlet system for providing a second process gas into the multiple plasma-generating portions to form the plasma.

3. The thin-film deposition apparatus according to claim 2, wherein the second process gas comprises silicon methane, argon, hydrogen, oxygen or the combination thereof.

4. The thin-film deposition apparatus according to claim 1, wherein the first gas inlet system comprises a first precursor gas source for providing a first precursor gas, a second precursor gas source for providing a second precursor gas, and a clean gas source for providing a clean gas, wherein the first precursor gas is able to react with the second precursor gas.

5. The thin-film deposition apparatus according to claim 4, wherein the clean gas comprises nitrogen.

6. The thin-film deposition apparatus according to claim 5, further comprising a first precursor gas supply connecting with the chamber for dispensing the first precursor gas, the second precursor gas and the clean gas from the chamber.

7. The thin-film deposition apparatus according to claim 1, wherein the chamber comprises a lower chamber, an upper chamber on the lower chamber and a fixing part for connecting the lower chamber and the upper chamber.

8. The thin-film deposition apparatus according to claim 7, wherein the carrier is in the lower chamber and the showerhead is in the upper chamber.

9. The thin-film deposition apparatus according to claim 1, further comprising a gas barrier on the carrier.

10. The thin-film deposition apparatus according to claim 9, wherein the gas barrier comprises multiple drain channels on thereof.

11. A method of thin-film deposition, comprising steps of:
providing a chamber;
proving a substrate in the chamber;
forming a first thin film on the substrate in a first thin-film deposition mode; and
forming a second thin film on the first thin film in a second thin-film deposition mode;
wherein the first thin-film deposition mode comprises Atomic Layer Deposition, the second thin-film deposition mode comprises Plasma Enhanced Chemical Vapor Deposition, and the first thin-film deposition mode and the second thin-film deposition mode are performed in the chamber.

12. A thin-film deposition apparatus, comprises:
a chamber;
a carrier in the chamber; and
a showerhead on the carrier,
wherein the shower comprises:
an upper surface;
a lower surface opposite to the upper surface, wherein the lower surface comprises a normal;
multiple first gas-dispensing holes on the lower surface;
a gas inlet hole, wherein a first process gas is transferred into the multiple first gas-dispensing holes through the gas inlet hole; and
a gas supply pipeline connecting between the gas inlet hole and the multiple first gas-dispensing holes,
wherein the first process gas enters the multiple first gas-dispensing holes through the gas supply pipeline;
wherein the first process gas can be dispensed from the first gas-dispensing hole in a gas dispensing direction, and the gas dispensing direction and the normal have an acute angle β between thereof.

13. The thin-film deposition apparatus according to claim 12, further comprises a first gas plate and a second gas plate disposed on the first gas plate.

14. The thin-film deposition apparatus according to claim 13, wherein the first gas plate comprises a first upper surface and a second lower surface opposite to the first upper surface

15. The thin-film deposition apparatus according to claim 14, wherein the first gas plate comprises multiple first recesses with first diameters, which are arranged at intervals of a first distance d1 and formed on the first upper surface, and each of the multiple first recesses comprises a first gas-dispensing hole with a second diameter r2 penetrating the first gas plate 150A to the first lower surface.

16. The thin-film deposition apparatus according to claim 13, wherein the second gas plate comprises a second upper surface and a second lower surface, and the second gas plate has the gas inlet hole and the gas supply pipeline.

17. The thin-film deposition apparatus according to claim 12, wherein 30°≦β≦60°.

18. The thin-film deposition apparatus according to claim 12, wherein part of the multiple first gas-dispensing holes and a center of the lower surface form a straight line, and the gas dispensing direction has a horizontal component parallel with the lower surface, wherein the horizontal component is perpendicular to the straight line.

19. The thin-film deposition apparatus according to claim 12, further comprising multiple branches connecting between the gas supply pipeline and the multiple first gas-dispensing holes.

20. The thin-film deposition apparatus according to claim 19, wherein the branch comprises a curved portion.
